(19) United States
(12) Patent Application Publication
(10) Pub. No.: US 2009/0123876 A1
(43) Pub. Date: May 14, 2009

(54) Optical disc and method of producing the same

(75) Inventors: Katsunori OHSHIMA, Kamakura-shi (JP); Kenji OISHI, Yokohama-shi (JP); Koji TSUJITA, Yokohama-shi (JP); Kenichi SHIMOMAI, Mito-shi (JP)

Correspondence Address: RENNER KENNER GREIVE BOBAK TAYLOR & WEBER, FIRST NATIONAL TOWER FOURTH FLOOR, 106 S. MAIN STREET, AKRON, OH, 44308, US

(73) Assignee: Victor Company of Japan, Ltd. a corporation of Japan, Yokohama-shi (JP)

(21) Appl. No.: 12/317,694

(22) Filed: Dec. 23, 2008

Related U.S. Application Data
(62) Division of application No. 11/284,722, filed on Nov. 22, 2005.

(30) Foreign Application Priority Data
Nov. 22, 2004 (JP) 2004-337246
May 23, 2005 (JP) 2005-149272
Oct. 12, 2005 (JP) 2005-297352

(51) Int. Cl. G03F 7/20

(52) U.S. Cl. 430/321

(57) ABSTRACT

An optical disk has a first and a second intermediate disk structure. The first structure includes at least a first transparent substrate, a first recording layer, and a first reflective layer. The first substrate has a first surface and a second surface. The first surface is a beam incidence surface for a laser beam in recording or reproduction of data. The second surface has a first concave section and a first convex section formed thereon. The first recording layer and the first reflective layer are stack in order on the second surface via the first concave and convex sections. The second structure includes at least a second substrate, a second reflective layer, and a second recording layer. The second substrate has a second concave section and a second convex section formed thereon. The second reflective layer and the second recording layer are stack in order on the second substrate via the second concave and convex sections. The first and second structures are bonded to each other so that the first reflective layer faces the second recording layer, the first concave section becomes closer to the beam incidence surface than the first convex section does, and the second concave section becomes closer to the beam incidence surface than the second convex section does. The first recording layer has a first data-storage area on the first concave section. The second recording layer has a second data-storage area on the second concave section. Each of the first and second convex sections has at least one pre-pit formed thereon. The pre-pit carries auxiliary information related to the data to be recorded or reproduced.

### CROSS-REFERENCE TO RELATED APPLICATIONS

This application is a division of U.S. patent application Ser. No. 11/284,722 filed Nov. 22, 2005.

This application is based on and claims the benefit of priority from the prior Japanese Patent Application No. 2004-337246 filed on Nov. 22, 2004, No. 2005-149272 filed on May 23, 2005, and No. 2005-297352 filed on Oct. 12, 2005, the entire contents of which are incorporated herein by reference.

### BACKGROUND OF THE INVENTION

The present invention relates to an optical disk having two or more of recording layers and a method of producing such an optical disk.

Optical disks, such as DVDs, having two recording layers have been developed to meet the demands of storing a large amount of information.

Japanese Patent Un-examined Publication No. 2001-266402 discloses an optical disk (a single-sided dual-layer optical disk) having two recording layers on one side. In detail, the optical disk has a first polycarbonate substrate and a second polycarbonate substrate. Formed in order on the first substrate are a ZnS—SiO₂ protective film, a first recording layer of InSbTe, and a ZnS—SiO₂ protective film. Formed in order on the second substrate are an Al—Cr reflective film, a ZnS—SiO₂ protective film, a second recording layer of GeSbTe, a ZnS—SiO₂ protective film, and an Au interference layer. The first and second substrates are bonded to each other via an ultraviolet (UV)-cured resin.

Recording and reproduction to and from the single-sided dual-layer optical disk can be done with focusing laser beams via the first substrate onto the first and second recording layers.

The first and second substrates are produced as described below with reference to FIG. 1.

As shown in (A) of FIG. 1, a photoresist 29 is applied onto a glass substrate 28. The photoresist 29 is exposed to a laser beam Le and then developed, thus a photoresist pattern 30 being formed, as shown in (B) of FIG. 1. Thus, a glass master plate 31 constituted by the glass substrate 28 and the photoresist pattern 30 is formed.

Next, as shown in (C) of FIG. 1, nickel is applied onto the photoresist pattern 30 by electroforming, thus a stamper 32 is produced on the photoresist pattern 30.

A first substrate 33 is then produced by resin injection molding using the stamper 32, as shown in (D) of FIG. 1, having a concave section 33a and a convex section 33b which become a spiral groove and land, respectively. The concave section 33a is formed as wobbling on both sides. At the same time, land pre-pits carrying auxiliary information, such as addresses, are formed on the land, with the same depth as the concave section 33a.

A second substrate 38 (shown in FIG. 2) is produced almost in the same way as the first substrate 33.

The first and second substrates produced as described above are bonded to each other, thus a single-sided dual-layer optical disk being produced, with the land pre-pits formed on the lands as described above.

Such a single-sided dual-layer optical disk has, however, disadvantages as follows:

In recording or reproduction, a laser beam is focused onto the recording layer formed on the concave section when viewed from a beam incident surface. In detail, for the first substrate 33, recording or reproduction is performed to or from the first recording layer formed on the groove (the concave sections 33a in (D) of FIG. 1). In contrast, for the second substrate, recording or reproduction is performed to or from the second recording layer formed on the land (corresponding to the convex section when the second substrate is produced as shown in FIG. 1) having the land pre-pits, or to or from the concave sections when viewed from the beam incident surface.

Recording or reproduction to or from the second substrate thus requires addressing to avoid the land pre-pits. In other words, recording or reproduction laser beams controlled differently have to be used for the first and second substrates.

The concave and convex sections for the second substrate are formed by applying a photoresist pattern with exposure to a laser beam and development, like shown in (A) and (B) of FIG. 1, followed by etching the exposed substrate. The concave section of the second substrate when viewed from a beam incident surface for recording or reproduction is covered with a photoresist pattern and thus cannot be irradiated with a laser beam in exposure. In contrast, the convex section of the second substrate when viewed from the beam incident surface is not covered with the photoresist pattern and thus irradiated with a laser beam in exposure.

A laser beam for use in exposure exhibits a particular Gaussian distribution in which optical intensity is strongest at the beam center and gradually becomes weaker as closer to the beam periphery. Thus, the area of the second substrate corresponding to the beam periphery is not exposed enough. Therefore, the border between the convex and concave sections becomes blurred with respect to an incident surface for a laser beam in recording or reproduction.

For the second substrate, recording or reproduction is performed to or from the second recording layer formed on the concave section when viewed from the beam incident surface, as discussed above. The recording width is, however, not constant because the border between the convex and concave sections becomes blurred. This causes jitters, variation in amplitude, etc., in recording or reproduction.

Optical disks having three or more of recording layers also suffer from the problems discussed above.

Illustrated in FIG. 2 is a second recording layer 34 formed on the second substrate 38 of the known single-sided dual-layer optical disk produced as described above.

The second recording layer 34 is formed as having a uniform thickness in a zone in which a land pre-pit 37 of a land (a convex section 35) is formed and another zone in which a groove (a concave section 36) is formed.

When a recorded mark is formed on the second recording layer 34 of the concave section 36 by emitting a laser beam Lr for recording, another recorded mark is inevitably formed on the second recording layer 34 of the convex section 35 due to heat dissipation of the laser beam Lr. Thus, the other recorded mark is also picked up when exposed to a laser beam in reproduction, which causes crosstalk and hence enough amplitude is not gained for a land pre-pit signal.

Moreover, the size of a recorded mark depends on its location with respect to a land pre-pit. This causes variation in amplitude of a land pre-pit signal, which further causes increase in error rate.

### SUMMARY OF THE INVENTION

A purpose of the present invention is to provide an optical disk having two or more of recording layers and a method of producing such an optical disk, with excellent recording and reproduction performances with common addressing to the recording layers.

Another purpose of the present invention is to provide an optical disk having two or more of recording layers and a method of producing such an optical disk, with accurate land pre-pit detection capability even after recorded marks are formed on a second recording layer formed on a concave section when viewed from an incident surface for a laser beam in recording or reproduction.

The present invention provides an optical disk comprising: a first intermediate disk structure including at least a first transparent substrate, a first recording layer, and a first reflective layer, the first transparent substrate having a first surface and a second surface, the first surface being a beam incidence surface for a laser beam in recording or reproduction of data, the second surface having a first concave section and a first convex section formed thereon, the first recording layer and the first reflective layer being stack in order on the second surface via the first concave and convex sections; and a second intermediate disk structure including at least a second substrate, a second reflective layer, and a second recording layer, the second substrate having a second concave section and a second convex section formed thereon, the second reflective layer and the second recording layer being stack in order on the second substrate via the second concave and convex sections, wherein the first and second intermediate disk structures are bonded to each other so that the first reflective layer faces the second recording layer, the first concave section becomes closer to the beam incidence surface than the first convex section does, and the second concave section becomes closer to the beam incidence surface than the second convex section does, the first recording layer having a first data-storage area on the first concave section, the second recording layer having a second data-storage area on the second concave section, each of the first and second convex sections having at least one pre-pit formed thereon, the pre-pit carrying auxiliary information related to the data to be recorded or reproduced.

Moreover, the present invention provides a method of producing an optical disk comprising the steps of: producing a first transparent substrate having a first surface and a second surface, by using a pre-produced first master stamper, the first surface being a beam incidence surface for a laser beam in recording or reproduction, and the second surface having a first concave section and a first convex section formed thereon, the first convex section having at least one first pre-pit; forming at least a first recording layer and a first reflective layer in order on the first substrate via the first concave and convex sections, thus producing a first intermediate disk structure; producing a second substrate, by using a mother stamper that is produced by transfer of a pre-produced second master stamper, the second substrate surface having a second concave section and a second convex section formed thereon, the second concave section having at least one second pre-pit; forming at least a second reflective layer and a second recording layer in order on the second substrate via the second concave and convex sections, thus producing a second intermediate disk structure; and bonding the first and second intermediate disk structures each other so that the first reflective layer faces the second recording layer.

Furthermore, the invention provide a method of producing an optical disk comprising the steps of: producing a first transparent substrate having a first surface and a second surface, by using a pre-produced first master stamper, the first surface being a beam incidence surface for a laser beam in recording or reproduction, and the second surface having a first concave section and a first convex section formed thereon, the first convex section having at least one first pre-pit; forming at least a first recording layer and a first reflective layer in order on the first substrate via the first concave and convex sections and the first pre-pit, thus producing a first intermediate disk structure; applying a photoresist onto a glass substrate, followed by exposure and development to form a photoresist pattern on the photoresist, the photoresist pattern having a concave section and a first opening reaching a surface of the glass substrate, followed by first dry etching to a first surface portion of the glass substrate exposed through the first opening to form a first hole in the glass substrate; ashing the photoresist pattern to remove the concave section thereof, thus a second surface portion of the glass substrate being exposed, followed by second dry etching to the glass substrate through the second exposed surface and the first hole to form a second opening in the second exposed surface and to dig the first hole by the same depth as the second opening to from a second hole, followed by removal of the photoresist pattern, thus producing a glass master plate; producing a master stamper by transfer of the glass master plate, followed by production of a mother stamper by transfer of the master stamper, thus producing a second substrate having a second concave section and a second convex section formed thereon, the second concave section having at least second pre-pit, the second pre-pit being higher than the second convex section, by using the mother stamper; forming at least a second recording layer and a second reflective layer in order on the second substrate via the second concave and convex sections and the second pre-pit, thus producing a second intermediate disk structure; and bonding the first and second intermediate disk structures each other so that the first reflective layer faces the second recording layer.

### BRIEF DESCRIPTION OF DRAWINGS

FIG. 1 is an illustration with sectional views showing production of a first and a second substrate in a known optical disk;

FIG. 2 is a sectional view illustrating a second recording layer formed on grooves and land pre-pit forming zones, with a uniform thickness in the known optical disk;

FIG. 3A is a sectional view illustrating an optical disk of a first preferred embodiment according to the present invention;

FIG. 3B is a perspective view, in a track direction T, illustrating a first substrate viewed from an M-M plane in FIG. 3A;

FIG. 3C is a perspective view, in a track direction T, illustrating a second substrate viewed from an N-N plane in FIG. 3A;

FIG. 4A is a sectional view illustrating photoresist application in a method of producing a first intermediate disk structure in the first embodiment;

FIG. 4B is a sectional view illustrating production of a glass master plate in the method of producing the first intermediate disk structure in the first embodiment;

FIG. 4C is a sectional view illustrating production of a master stamper in the method of producing the first intermediate disk structure in the first embodiment;

FIG. 4D is a sectional view illustrating production of a first substrate in the method of producing the first intermediate disk structure in the first embodiment;

FIG. 4E is a sectional view illustrating production of a first recording layer in the method of producing the first intermediate disk structure in the first embodiment;

FIG. 4F is a sectional view illustrating production of a first reflective layer in the method of producing the first intermediate disk structure in the first embodiment;

FIG. 4G is a sectional view illustrating production of a first transparent protective layer in the method of producing the first intermediate disk structure in the first embodiment;

FIG. 5A is a sectional view illustrating photoresist application in a method of producing a second intermediate disk structure in the first embodiment;

FIG. 5B is a sectional view illustrating production of a glass master plate in the method of producing the second intermediate disk structure in the first embodiment;

FIG. 5C is a sectional view illustrating production of a master stamper in the method of producing the second intermediate disk structure in the first embodiment;

FIG. 5D is a sectional view illustrating production of a mother stamper in the method of producing the second intermediate disk structure in the first embodiment;

FIG. 5E is a sectional view illustrating production of a second substrate in the method of producing the second intermediate disk structure in the first embodiment;

FIG. 5F is a sectional view illustrating production of a second reflective layer in the method of producing the second intermediate disk structure in the first embodiment;

FIG. 5G is a sectional view illustrating production of a second recording layer in the method of producing the second intermediate disk structure in the first embodiment;

FIG. 5H is a sectional view illustrating production of a second transparent protective layer in the method of producing the second intermediate disk structure in the first embodiment;

FIG. 6 is a sectional view illustrating bonding of the first and second intermediate disk structures in the first embodiment;

FIG. 7A is a sectional view illustrating an optical disk of a second preferred embodiment according to the present invention;

FIG. 7B is a perspective view, in a track direction T, illustrating a second substrate viewed from a P-P plane in FIG. 7A;

FIG. 8A is a sectional view illustrating photoresist application in a method of producing a first intermediate disk structure in the second embodiment;

FIG. 8B is a sectional view illustrating formation of a photoresist pattern in the method of producing the first intermediate disk structure in the second embodiment;

FIG. 8C is a sectional view illustrating a first dry etching process in the method of producing the first intermediate disk structure in the second embodiment;

FIG. 8D is a sectional view illustrating a ashing process in the method of producing the first intermediate disk structure in the second embodiment;

FIG. 8E is a sectional view illustrating a second dry etching process and a glass master plate production process in the method of producing the first intermediate disk structure in the second embodiment;

FIG. 8F is a sectional view illustrating production of a master stamper in the method of producing the first intermediate disk structure in the second embodiment;

FIG. 8G is a sectional view illustrating production of a mother stamper in the method of producing the first intermediate disk structure in the second embodiment; and

FIG. 8H is a sectional view illustrating production of a second substrate in the method of producing the first intermediate disk structure in the second embodiment.

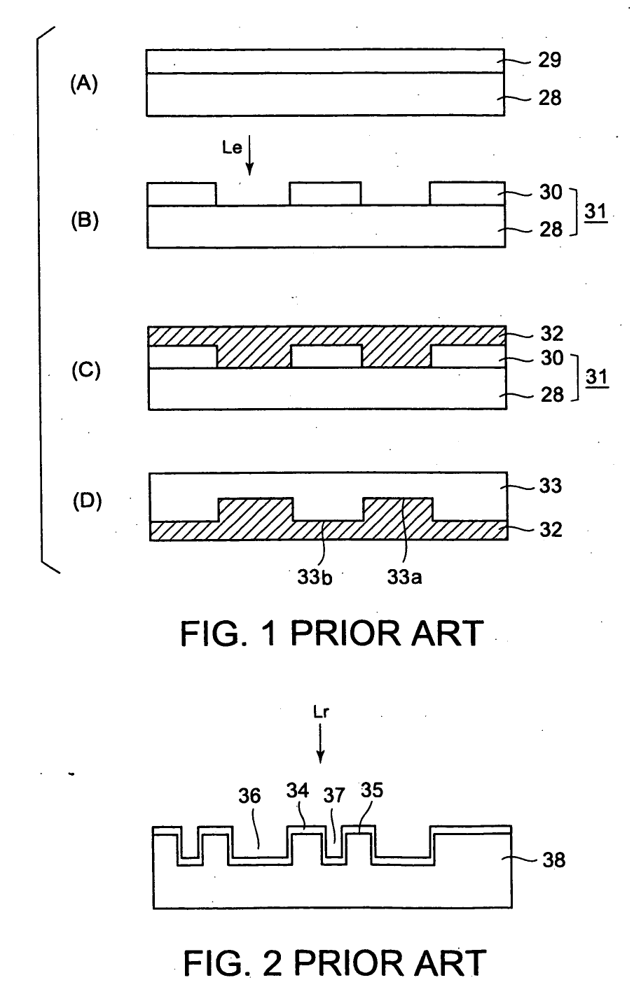

### DETAILED DESCRIPTION OF PREFERRED EMBODIMENTS

Several embodiments of an optical disk and a production method for such an optical disk according to the present invention will be disclosed with reference to the attached drawings.

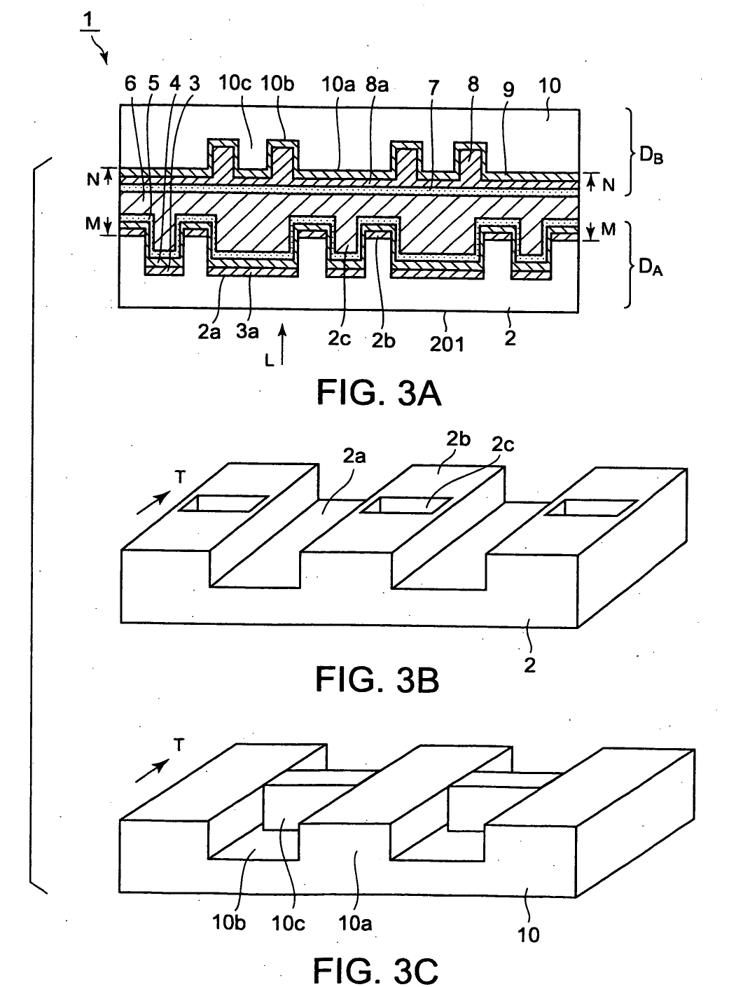

The same reference signs or numerals are given to the same or analogous elements throughout figures. The figures are not drawn in scale and exaggerated particularly in the thickness direction for easier understanding. Especially, a second recording layer 8 is indicated as flat in its surface for brevity in FIGS. 3A, 5G, 5H, 6 and 7A,

A first preferred embodiment of an optical disk according to the present invention will be disclosed with reference to FIGS. 3A to 3C.

As shown in FIGS. 3A to 3C, an optical disk 1 has a first disk-like substrate 2 having first concave and convex sections 2a and 2b and a second disk-like substrate 10 having second concave and convex sections 10a and 10b. Formed in order on the first substrate 2 are a first recording layer 3, a first reflective layer 4, and a first transparent protective layer 5. Formed in order on the second substrate 10 are a second reflective layer 9, a second recording layer 8, and a second transparent protective layer 7. The first and second substrates 2 and 10 are bonded to each other via a transparent adhesive layer 6.

The stacked layers from the first substrate 2 to the first transparent protective layer 5 constitute a first intermediate disk structure D_{A}. The other stacked layers from the second transparent protective layer 7 to the second substrate 10 constitute a second intermediate disk structure D_{B}.

The first concave and convex sections 2a and 2b, and the second concave and convex sections 10a and 10b, formed on the first and second substrates 2 and 10, respectively, are defined as below in the following disclosure.

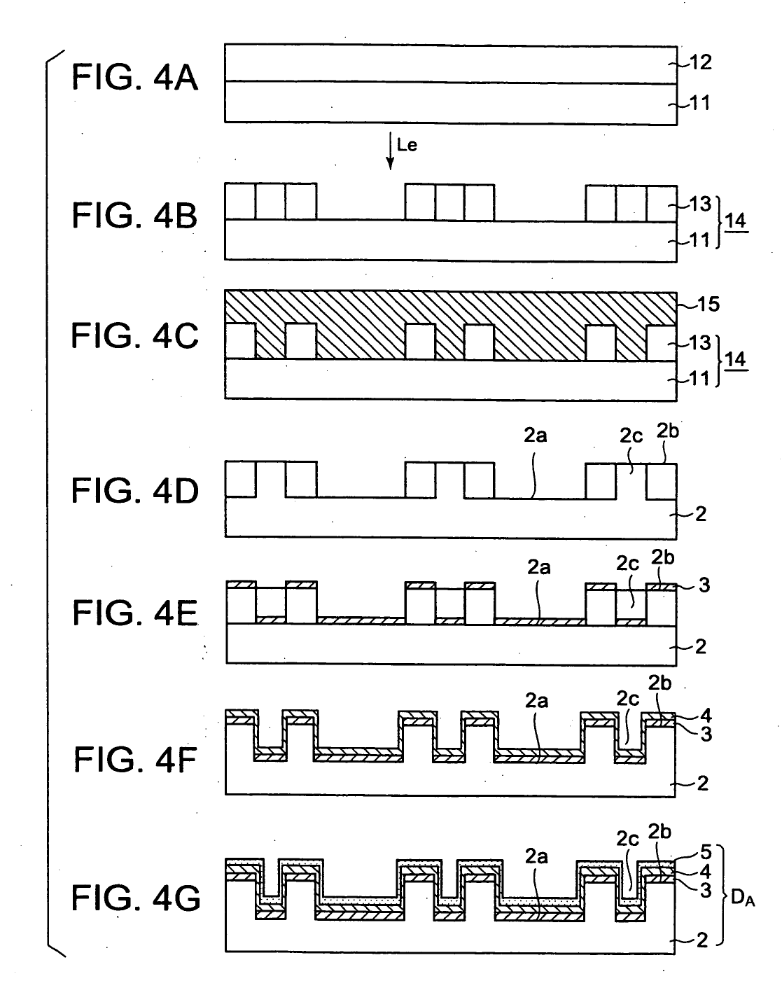

The sections closer to a beam incident surface 201 for a laser beam L in recording or reproduction are defined as concave sections. In contrast, the sections far from the incident surface 201 are defined as convex sections. These defined concave and convex sections are further defined as grooves and lands, respectively. In FIGS. 3A to 3C, the sections 2a and 10a, and the sections 2b and 10b are grooves and lands, respectively, according to the definition, the same as true for FIGS. 4A to 4G which will be explained later.

These definitions are applied to those sections when the first and second intermediate disk structures D_{A} and D_{B} are bonded to each other, as shown in FIG. 3A, the same as true for a second preferred embodiment, which will be explained later.

Data are recorded on the first and second recording layers 3 and 8 formed on the grooves 2a and 10a, respectively. The areas of the recording layers 3 and 8 formed on the grooves 2a and 10a, respectively, for storing data are defined as data-storage areas 3a and 8a, respectively. Formed on the lands 2b and 10b are land pre-pits 2c and 10c, respectively, which carry auxiliary information, such as, an address and a synchronous signal.

The groove 2a and land 2b are formed as adjacent to each other and alternately on the first substrate 2. As shown in FIG. 3B, the land 2b has land pre-pits 2c formed thereon which carry auxiliary information, such as, an address and a synchronous signal. A plurality of land pre-pits 2c are formed as a pattern having the same height as the land 2b. In other words, these land pre-pits 2c are formed as pits which are concave sections scattered over the land 2b.

Each of the groove 2a and land 2b is formed continuously and spirally from the inner to outer periphery or vice versa on the first substrate 2. The groove 2a is wobbling on both sides. First data is recorded to or reproduced from the data-storage area 3a of the first recording layer 3 formed on the groove 2a.

The groove 10a and land 10b are formed as adjacent to each other and alternately on the second substrate 10 that faces the first substrate 2. As shown in FIG. 3C, the land 10b has land pre-pits 10c formed thereon. A plurality of land pre-pits 10c are formed as a pattern having the same height as the groove 10a. In other words, these land pre-pits 10c are formed as pits which are concave sections scattered over the land 10b.

Each of the groove 10a and land 10b is formed continuously and spirally from the inner to outer periphery or vice versa on the second substrate 10, like the groove 2a and land 2b. The groove 10a is wobbling on both sides. Second data is recorded to or reproduced from the data-storage area 8a of the second recording layer 8 formed on the groove 10a.

A suitable material for the first substrate 2 is a transparent material, such as, polycarbonate resin, polymethacrylic ester resin, and amorphous polyolefin resin. The second substrate 10 may not be transparent because it is not provided at the beam-incident side for the laser beam L in recording or reproduction. Nevertheless, it is preferable to use the same material as the first substrate 2 for the second substrate 10.

A suitable material for the first and second recording layers 3 and 8 is cyanine dye, phthalocyanine dye or azoic dye soluble in a polar solvent, such as alcohol or Cellosolve solvent.

The second recording layer 8 formed on the groove 10a is thicker than a height of the land 10b, which gives more flat concave and convex sections on the layer 8 than the steps formed by the groove 10a and land 10b.

When any of the materials mentioned above is used for the first and second recording layers 3 and 8, the transparent protective layers 5 and 7 are preferably provided to protect the layers 3 and 8 which could otherwise be damaged in a bonding process in a disk production method disclosed later.

A suitable material for the first and second transparent protective layers 5 and 7 is a transparent resin that is soluble in a particular solution that does not dissolve an organic dye.

Such an organic solution is preferably a nonpolar solution, for example, Cyclohexane, Tetralin or Decalin. A transparent dye soluble in such a nonpolar solution is preferably cyclic amorphous polyolefin (Zeonex® or Qinton® made by Zeon Co.).

The first and second transparent protective layers 5 and 7 can be made with the solution described above by spin coating.

Other choices for the first and second transparent protective layers 5 and 7 are a semi-transparent metallic reflective layer and an inorganic transparent thin-film layer. When such an alternative is used, the layers 5 and 7 may have a function of adjusting optical transmissivity. In detail, adjustments to refraction index “n” to a wavelength of a laser beam in recording or reproduction, absorption coefficient “k”, and thickness for the protective layers 5 and 7 offer higher reflectivity to the first and second recording layers 3 and 8 and also higher optical transmissivity to the second recording layer 8.

A suitable material for the first and second transparent protective layers 5 and 7 with such a function is an inorganic dielectric film of sulfide, oxide or nitride, such as ZnS (n=2.4), SiC (n=2.2), TiO₂ (n=2.5), SiN (n=2.1) and ZnS—SiO₂ (n=2.1).

Still, another choice for the first and second transparent protective layers 5 and 7 is a UV-cured resin with metallic or ceramic microparticles mixed therein. This compound gives higher refraction index “n” to the layers 5 and 7.

Further choice for the first and second transparent protective layers 5 and 7 is a dual-layer structure having a transparent resin thin-film layer of cyclic amorphous polyolefin mentioned above and a semi-transparent metallic reflective layer or an inorganic transparent thin-film layer.

The first and second reflective layers 4 and 9 are preferably made of Au, Al, Ag or an alloy of any of these metals for higher reflectivity. Such a material gives higher reflectivity to the second reflective layer 9 when a laser beam is reflected thereon in recording or reproduction because the second recording layers 8 is planarized.

A material for the transparent adhesive layer 6 is preferably an acryrate UV-cured resin for higher productivity and yielding. Main ingredients of such a resin are, for example, epoxyacryrate, urethanacryrate, and the mixture of these materials.

After applied with such a UV-cured resin by spin coating, the first and second intermediate disk structures D_{A} and D_{B} are attached to each other and then bonded to each other with irradiation of ultraviolet rays. Thus, a single-sided dual-layer optical disk 1 that exhibits higher reflectivity and signal modulation factor is produced.

As disclosed above, in the single-sided dual-layer optical disk 1, recording or reproduction is performed to or from the data-storage areas 3a and 8a in the first and second recording layers 3 and 8, respectively, which are formed on the grooves 2a and 10a, respectively. Such storage-area allocation allows addressing common to the both recording layers, thus offering excellent recording and reproduction performances.

The second recording layer 8 covers the groove 10a and land 10b. The surface of the layer 8 is more flat than the steps of the groove 10a and land 10b. In recording or reproduction, a laser beam exhibits a particular phase difference when reflected from the planarized surface of the layer 8. This particular phase difference gives a higher reflectivity to the single-sided dual-layer optical disk 1.

Disclosed next with reference to FIGS. 4A to 4G, FIGS. 5A to 5H and FIG. 6 is a method of producing the single-sided dual-layer optical disk 1, the first preferred embodiment according to the present invention.

[Glass Master Plate Production Process for First Substrate]

As shown in FIG. 4A, a photoresist 12 is applied onto a disk-like glass substrate 11. The photoresist 12 is exposed to a laser beam Le and then developed, thus a photoresist pattern 13 being formed from the inner to outer periphery or vice versa on the substrate 11, as shown in FIG. 4B. Thus, a glass master plate 14 constituted by the glass substrate 11 and the photoresist pattern 13 is produced. The pattern 13 is used for forming the groove 2a, the land 2b and the land pre-pit 2c on the land 2b (FIGS. 3A and 3B), as disclosed later. The pattern 13 is formed as wobbling on both sides. Moreover, a portion of the pattern 13 corresponding to the groove 2a is formed as a single concave section that is spiral and continuous from the inner to outer periphery or vice versa on the substrate 11.

[Master Stamper Production Process for First Substrate]

As shown in FIG. 4C, nickel is applied at a thickness in the range from 50 to 200 nm on the glass master plate 14 by sputtering. Then, a nickel film having a thickness in the range from 100 to 500 μm is formed thereon by electroforming, thus the photoresist pattern 13 being transferred to form a master stamper 15. The stamper 15 has an inverse pattern to that of the photoresist pattern 13.

[First Substrate Production Process]

The master stamper 15 is attached to an injection molding machine (not shown). A first substrate 2 is then produced by resin injection molding, which has a groove 2a and a land 2b with land pre-pits 2c thereon, formed from the inner to outer periphery or vice versa, as shown in FIG. 4D.

[First Recording Layer Production Process]

As shown in FIG. 4E, an organic dye dissolved in a solvent like alcohol is applied onto the first substrate 2 by spin coating, thus a first recording layer 3 being formed. The first recording layer 3 seems to have a uniform thickness in FIG. 4E. It is, however, actually, thicker on the groove 2a than the land 2b because the organic dye is flown into the groove 2a lower than the land 2b. Thus, no organic dye is formed on the side walls of the land 2b and the land pre-pits 2c. The organic dye formed on portions of the land 2b with the pre-pits 2c formed thereon is thicker than that formed on other portions of the land 2b with no pre-pits formed thereon.

[First Reflective Layer Production Process]

As shown in FIG. 4F, a first reflective layer 4 is formed on the first recording layer 3 by sputtering or vacuum deposition.

[First Transparent Protective Layer Production Process]

As shown in FIG. 4G, a transparent resin made of a thermoplastic resin dissolved in a nonpolar solution is applied onto the first reflective layer 4, thus a first transparent protective layer 5 being formed. An alternative to the transparent resin is a semi-transparent metallic reflective layer, an inorganic transparent thin-film layer, etc.

Through the processes disclosed above, a first intermediate disk structure D_{A} is produced.

[Master Stamper Production Process for Second Substrate]

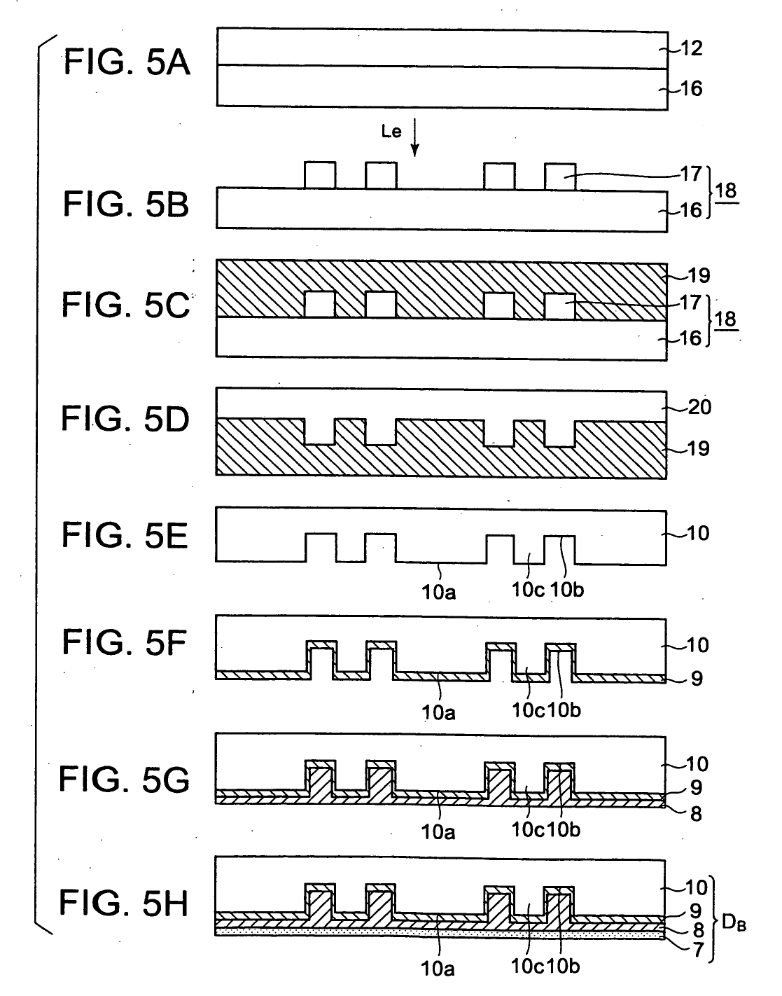

As shown in FIG. 5A, a photoresist 12 is applied onto a disk-like glass substrate 16. The photoresist 12 is exposed to a laser beam Le and then developed, thus a photoresist pattern 17 being formed from the inner to outer periphery or vice versa on the substrate 16, as shown in FIG. 5B. Thus, a glass master plate 18 constituted by the glass substrate 16 and the photoresist pattern 17 is produced. The pattern 17 is used for forming the groove 10a, the land 10b, and the land pre-pit 10c on the land 10b (FIGS. 3A and 3C), as disclosed later. The pattern 17 is formed as wobbling on both sides. A portion of the pattern 17 that corresponds to the groove 10a is formed as a single concave section that is spiral and continuous from the inner to outer periphery or vice versa on the substrate 16.

[Master Stamper Production Process for Second Substrate]

As shown in FIG. 5C, nickel is applied at a thickness in the range from 50 to 200 nm on the glass master plate 18 by sputtering. Then, a nickel film having a thickness in the range from 100 to 500 μm is formed thereon by electroforming, thus a master stamper 19 being produced. The stamper 19 has an inverse pattern to that of the glass master plate 18.

[Mother Stamper Production Process]

The master stamper 19 is removed from the glass master plate 18. As shown in FIG. 5D, a nickel film is formed on the master stamper 19 by electroforming, thus a pattern formed on the stamper 19 being transferred to form a mother stamper 20. The stamper 20 has a pattern identical to that of the glass master plate 18.

[Second Substrate Production Process]

The mother stamper 20 is attached to an injection molding machine (not shown). A second substrate 10 is then produced by resin injection molding, which has a groove 10a and a land 10b with land pre-pits 10c thereon, formed spirally from the inner to outer periphery or vice versa, as shown in FIG. 5E.

[Second Reflective Layer Production Process]

As shown in FIG. 5F, a second reflective layer 9 is formed on the second substrate 10 by sputtering or vacuum deposition.

[Second Recording Layer Production Process]

As shown in FIG. 5G, an organic dye dissolved in a solvent like alcohol is applied onto the second reflective layer 9 by spin coating, thus a second recording layer 8 being formed. The layer 8 is formed as thicker on the groove 10a than the land 10b. Thus, the surface of the layer 8 is more flat than the steps of the groove 10a and land 10b.

[Second Transparent Protective Layer Production Process]

As shown in FIG. 5H, a transparent resin made of a thermoplastic resin dissolved in a nonpolar solution is applied onto the second recording layer 8, thus a second transparent protective layer 7 being formed.

Through the processes disclosed above, a second intermediate disk structure D_{B} is produced.

[Bonding Process]

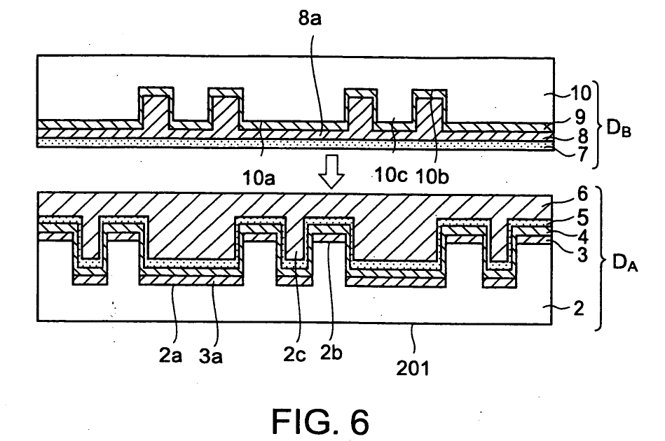

As shown in FIG. 6, a transparent adhesive layer 6 made of a UV-cured resin is applied on the first transparent protective layer 5 of the first intermediate disk structure D_{A}. The second intermediate disk structure D_{B} is then placed on the adhesive layer 6 so that the second transparent protective layer 7 faces the adhesive layer 6. The disk structures D_{A} and D_{B} are rotated so that the adhesive layer 6 is spread over the protective layer 7, followed by exposure to ultraviolet rays. Thus, the single-sided dual-layer optical disk 1 shown in FIG. 3A is produced.

An alternative to the UV-cured resin is an adhesive sheet having a releasable sheet with an adhesive material formed thereon. The adhesive sheet is pressed onto the first transparent protective layer 5 of the first intermediate disk structure D_{A} to release bubbles existing therebetween and adhered to the layer 5. The releasable sheet only is peeled off. The second intermediate disk structure D_{B} is then placed on the adhesive material so that the second transparent protective layer 7 faces the first transparent protective layer 5. The second intermediate disk structure D_{B} is then pressed to release bubbles and adhered, thus, the single-sided dual-layer optical disk 1 shown in FIG. 3A can be produced in this way.

As disclosed above, the first and second substrates 2 and 10 are produced with the master stamper 15 and the mother stamper 20, respectively. This allows the land pre-pits 2c and 10c to be formed on the lands 2b and 10b, respectively. This structure allows common addressing to the first and second recording layers 3 and 8 for excellent recording and reproduction.

Discussed next is evaluation of recording and reproduction characteristics of sample optical disks S1 to S3 with different materials for each layer that were produced in accordance with the first embodiment of the optical disk according to the present invention disclosed above.

The material used for first and second substrates 2 and 10 for the sample disks was a polycarbonate resin.

[Sample 1]

Produced first was a sample-1 first intermediate disk structure D_{A}.

A 0.6 mm-thick first substrate 2 with a 0.74 μm-track pitch was produced, using the master stamper 15, as having a groove 2a of 160 nm in depth and 0.3 μm in width, a land 2b of 160 nm in height from the bottom of the groove 2a and 0.44 μm in width, and land pre-pits 2c, on the land 2b, with a pattern having the same height as the land 2b.

Cyanine (S06-DX001® made by Hayashibara Co. Ltd.) exhibiting 585 nm in maximum absorption wavelength was dissolved in tetrafluoropropanol to prepare a 0.6-wt % solution.

The solution was applied onto the first substrate 2. The substrate 2 was then rotated at 3000 rpm in spin coating. Thus, a first recording layer 3 was formed as having thickness of 120 nm and 30 nm on the groove 2a and the land 2b, respectively. A 10 nm-thick Ag-made first reflective layer 4 was formed on the first recording layer 3 by sputtering.

A petroleum resin (Qinton1325® made by Zeon Co.) made of a copolyermer of cyclopentadiene and dicyclopentadiene, that is a thermoplastic resin exhibiting 125° C. in softening point, was dissolved in Cyclohexane (a nonpolar solution) to prepare a 6.0-wt % solution.

The solution was applied onto the first reflective layer 4. The first substrate 2 was then rotated at 1000 rpm in spin coating, thus a first transparent protective layer 5 was formed.

Accordingly, the sample-1 first intermediate disk structure D_{A} was produced.

Produced next was a sample-1 second intermediate disk structure D_{B}.

A 0.6 mm-thick second substrate 10 with a 0.74 μm-track pitch was produced, using the mother stamper 20, as having a groove 10a of 30 nm in depth and 0.3 μm in width, a land 10b of 30 nm in height from the bottom of the groove 10a and 0.44 μm in width, and land pre-pits 10c, on the land 10b, with a pattern having the same height as the land 10b. A 70 nm-thick Au-made second reflective layer 9 was formed on the second substrate 10 by sputtering.

Cyanine (S06-DX001® made by Hayashibara Co. Ltd.) exhibiting 585 nm in maximum absorption wavelength was dissolved in tetrafluoropropanol to prepare a 1.0-wt % solution.

The solution was applied onto the second reflective layer 9. The second substrate 10 was then rotated at 3000 rpm in spin coating. Thus, a second recording layer 8 was formed as having a thickness of 60 nm on the groove 10a.

A petroleum resin (Qinton1325® made by Zeon Co.) made of a copolyermer of cyclopentadiene and dicyclopentadiene, that is a thermoplastic resin exhibiting 125° C. in softening point, was dissolved in Cyclohexane (a nonpolar solution) to prepare a 6.0-wt % solution.

The solution was applied onto the second reflective layer 9. The second substrate 10 was then rotated at 1000 rpm in spin coating, thus a second transparent protective layer 7 was formed.

Accordingly, the sample-1 second intermediate disk structure D_{B} was produced.

The sample-1 first and second intermediate disk structures D_{A} and D_{B} were bonded to each other. In detail, a transparent adhesive layer 6 made of a UV-cured resin was applied on the first transparent protective layer 5 of the first intermediate disk structure D_{A}. The second intermediate disk structure D_{B} was then placed on the adhesive layer 6 so that the second transparent protective layer 7 faced the adhesive layer 6. The disk structures D_{A} and D_{B} were rotated at 2000 rpm so that the adhesive layer 6 was spread over the protective layer 7, with a thickness of 40 μm, followed by exposure to ultraviolet rays. The UV cure resin used for the transparent adhesive layer 6 was modified urethane acryate (World Lock®No. 811 made by Kyoritu Chemical & Co. Ltd.).

Accordingly, the sample-1 single-sided dual-layer optical disk S1 was produced.

[Sample 2]

Produced first was a sample-2 first intermediate disk structure D_{A}.

A 0.6 mm-thick first substrate 2 with a 0.74 μm-track pitch was produced, using the master stamper 15, as having a groove 2a of 150 nm in depth and 0.3 μm in width, a land 2b of 150 nm in height from the bottom of the groove 2a and 0.44 μm in width, and land pre-pits 2c, on the land 2b, with a pattern having the same height as the land 2b.

Cyanine (S06-DX001® made by Hayashibara Co. Ltd.) exhibiting 585 nm in maximum absorption wavelength was dissolved in tetrafluoropropanol to prepare a 1.0-wt % solution.

The solution was applied onto the first substrate 2. The substrate 2 was then rotated at 3000 rpm in spin coating. Thus, a first recording layer 3 was formed as having a thickness of 40 nm.

A 12 nm-thick first reflective layer 4 made of Ag₉₈Pd₁Cu₁ (atomic % in composition ratio) was formed on the first recording layer 3 by sputtering. Then, a 66 nm-thick first transparent protective layer 5 made ZnS—SiO₂ was formed on the first reflective layer 4.

Accordingly, the sample-2 first intermediate disk structure D_{A} was produced.

Produced next was a sample-2 second intermediate disk structure D_{B}.

A 0.6 mm-thick second substrate 10 with a 0.74 μm-track pitch was produced, using the mother stamper 20, as having a groove 10a of 120 nm in depth and 0.3 μm in width, a land 10b of 120 nm in height from the bottom of the groove 10a and 0.44 μm in width, and land pre-pits 10c, on the land 10b, with a pattern having the same height as the land 10b. A 100 nm-thick Ag-made second reflective layer 9 was formed on the second substrate 10 by sputtering.

Cyanine (S06-DX001® made by Hayashibara Co. Ltd.) exhibiting 585 nm in maximum absorption wavelength was dissolved in tetrafluoropropanol to prepare a 0.75-wt % solution.

The solution was applied onto the second reflective layer 9. The second substrate 10 was then rotated at 1000 rpm in spin coating. Thus, a second recording layer 8 was formed as having a thickness of 35 nm on the groove 10a.

A petroleum resin (Zeonex480R® made by Zeon Co.) made of a copolyermer of cyclopentadiene and dicyclopentadiene, that is a thermoplastic resin exhibiting 135° C. in softening point, was dissolved in Decalin (a nonpolar solution) to prepare a 2.0-wt % solution.

The solution was applied onto the second reflective layer 9. The second substrate 10 was then rotated at 2500 rpm in spin coating, thus a second transparent protective layer 7 was formed.

Accordingly, the sample-2 second intermediate disk structure D_{B} was produced.

The sample-2 first and second intermediate disk structures D_{A} and D_{B} were bonded to each other in the same way as in the sample 1, thus the sample-2 optical disk S2 was produced as having two recording layers 3 and 8 on one side. Modified urethane acryate (SD661® made by Dainippon Ink & Chemical Inc.) of 45 μm in thickness was used for the transparent adhesive layer 6.

[Sample 3]

A sample-3 first intermediate disk structure D_{A} was produced in the same way as in the sample 2.

A sample-3 second intermediate disk structure D_{B} was produced as explained below.

A 0.6 mm-thick second substrate 10 with a 0.74 μm-track pitch was produced, using the mother stamper 20, as having a groove 10a of 120 nm in depth and 0.3 μm in width, a land 10b of 120 nm in height from the bottom of the groove 10a and 0.44 μm in width, and land pre-pits 10c, on the land 10b, with a pattern having the same height as the land 10b. A 100-nm thick Ag-made second reflective layer 9 was formed on the second substrate 10 by sputtering.

A petroleum resin (Zeonex480R® made by Zeon Co.) made of a copolyermer of cyclopentadiene and dicyclopentadiene, that is a thermoplastic resin exhibiting 135° C. in softening point, was dissolved in Decalin (a nonpolar solution) to prepare a 0.2-wt % solution.

The solution was applied onto the second reflective layer 9. The second substrate 10 was then rotated at 2500 rpm in spin coating, thus a transparent resin layer (not shown) was formed on the second reflective layer 9.

Cyanine (S06-DX001® made by Hayashibara Co. Ltd.) exhibiting 585 nm in maximum absorption wavelength (in dichloromethane solution) was dissolved in tetrafluoropropanol to prepare a 0.75-wt % solution.

The solution was applied onto the transparent resin layer. The second substrate 10 was then rotated at 1000 rpm in spin coating. Thus, a second recording layer 8 was formed on the transparent resin layer, as having a thickness of 35 nm on the groove 10a.

A petroleum resin (Zeonex480R® made by Zeon Co.) made of a copolyermer of cyclopentadiene and dicyclopentadiene, that is a thermoplastic resin exhibiting 135° C. in softening point, was dissolved in Decalin (a nonpolar solution) to prepare a 2.0-wt % solution.

The solution was applied onto the second reflective layer 9. The second substrate 10 was then rotated at 2500 rpm in spin coating, thus a second transparent protective layer 7 was formed.

Accordingly, the sample-3 second intermediate disk structure D_{B} was produced.

The sample-3 first and second intermediate disk structures D_{A} and D_{B} were bonded to each other in the same way as in the samples 1 and 2, thus the sample-3 optical disk S3 was produced as having two recording layers 3 and 8 on one side. Modified urethane acryate (SD661® made by Dainippon Ink & Chemical Inc.) of 45 μm in thickness was used for the transparent adhesive layer 6.

[Evaluation of Recording/Reproduction]

Recording and reproduction characteristics were evaluated for the sample-1, -2 and -3 optical disks S1, S2 and S3 with an optical disk standard evaluator (DDU-1000 made by Pulse Tech Co., equipped with an objective lens with NA=0.65).

A recording/reproduction laser beam having a wavelength of 658 nm was focused onto the data-storage areas 3a and 8a of the first and second recording layers 3 and 8, respectively, from the first substrate 2 side while each sample disk was being rotated at a linear velocity of 7 m/s.

A DVD-format signal was recorded in the data-storage areas 3a and 8a for each sample disk at a recording peak power of 24 mW with recording strategy in accordance with the DVD-R standards.

Under these requirements, each sample exhibited low and high reflectivity in recorded and un-recorded sections, respectively, in the data-storage areas 3a and 8a of the first and second recording layers 3 and 8, respectively. This is so called “high to low” recording.

[Evaluation of Sample 1]

Evaluation results were: 7.5% in jitters in reproduction, 62% in modulation factor and 18% in reflectivity for the data-storage area 3a of the first recording layer 3; and 8.5% in jitters in reproduction, 65% in modulation factor and 19% in reflectivity for the data-storage area 8a of the second recording layer 8. It was thus confirmed that excellent recording was performed for both recording layers.

Moreover, addressing was successful with both land pre-pits 2c and 10c being detected from the first and second recording layers 3 and 8, respectively.

Accordingly, the sample-1 single-sided dual-layer optical disk is available to recording or reproduction of DVD format signals to or from the data-storage areas 3a and 8a of the first and second recording layers 3 and 8, respectively. Moreover, the sample 1 exhibited reflectivity within the read-only dual-layer DVD standards. It is thus confirmed that the sample 1 is compatible with read-only dual-layer DVDs.

[Evaluation of Sample 2]

Evaluation results were: 18% and 20% reflectivity in the data-storage areas 3a and 8a of the first and second recording layers 3 and 8, respectively, with almost the same results as the sample 1 for jitters in reproduction, modulation factor and addressing.

[Evaluation of Sample 3]

Recording was successful for the data-storage areas 3a and 8a of the first and second recording layers 3 and 8, respectively, with lower power than for the sample 2. Evaluation results were: 20% reflectivity for both of the first and second recording layers 3 and 8, with almost the same results as the samples 1 and 2 for jitters in reproduction, modulation factor and addressing.

Accordingly, addressing was successfully and equally made for both of the data-storage areas 3a and 8a of the first and second recording layers 3 and 8, respectively, thus excellent recording and reproduction being confirmed.

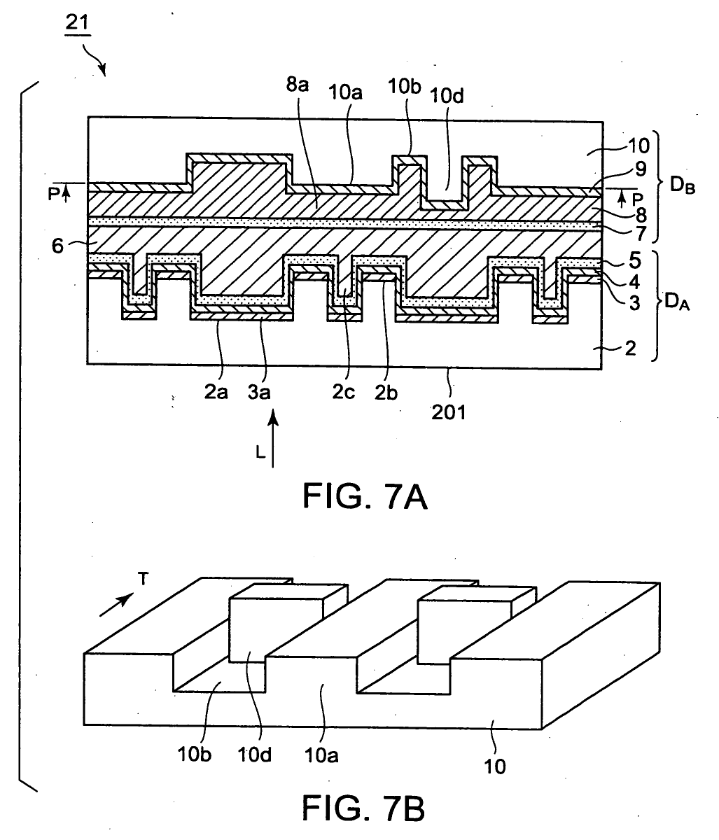

A second preferred embodiment of an optical disk according to the present invention will be disclosed with reference to FIGS. 7A and 7B.

Differences between the first embodiment and the second embodiment are as follows: As shown in FIGS. 7A and 7B, in the second embodiment, an optical disk 21 has land pre-pits 10d each formed on a second substrate 10 as protruding so that each pre-pit 10d is closer to the beam incident surface 201 for a laser beam L in recording or reproduction than the surface of the groove 10a is, different from that shown in FIGS. 3A and 3C. Moreover, the groove 10a in the second embodiment has a depth in the range from 20 to 40 nm. The other requirements are the same between the first and second embodiments.

The structure in which each land pre-pit 10d protrudes so that it is closer to the incident surface 201 than the surface of the groove 10a is prevents a recoded mark from being diffused towards the pre-pit 10d. The phenomenon could occur when the recorded mark is formed in the data-storage area 8a of the second recording layer 8, due to thermal diffusion. This structure prevents crosstalk in reproduction, thus offering enough amplitude to land pre-pit signals for lower error rate in reproduction.

Moreover, the second recording layer 8 formed on the groove 10a has a thickness larger than a height of the land 10b. This structure prevents decrease in reflectivity due to phase difference of a laser beam in reproduction from the data-storage area 8a, thus giving signals with higher C/N. Practically, the thickness of the second recording layer 8 three times or more larger than the height of the land 10b attains a more flat surface for higher reflectivity.

Under these requirements, stable recording and reproduction performances are achieved because the groove 10a has a depth in the range from 20 to 40 nm.

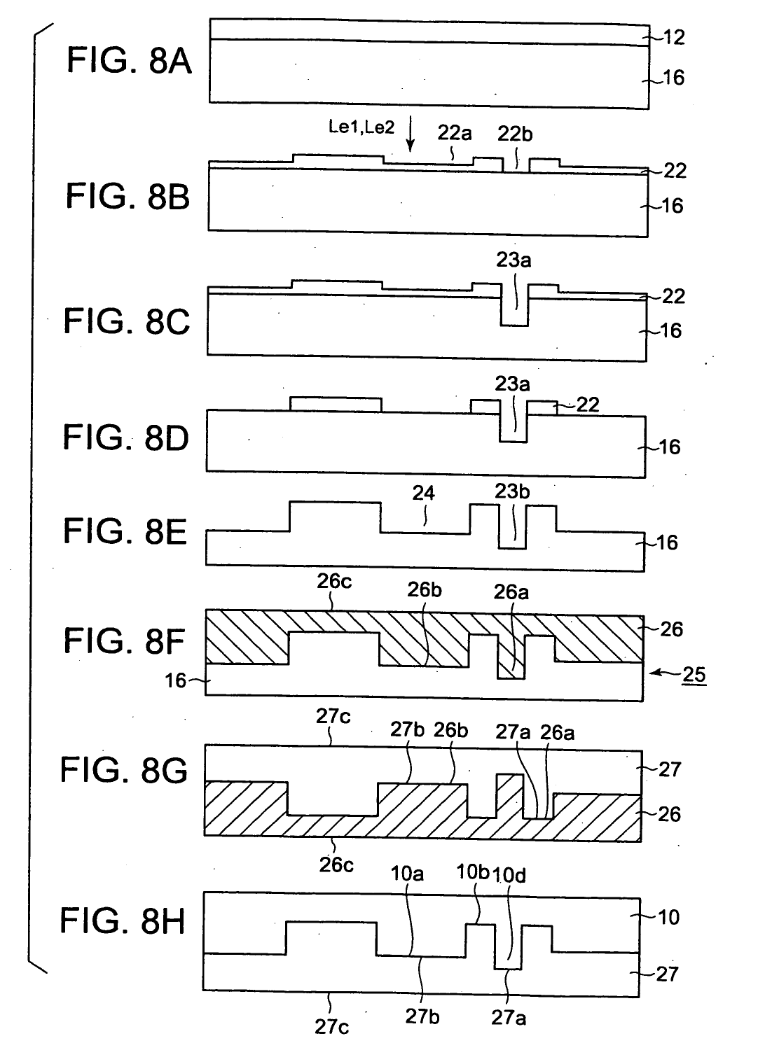

Disclosed next with reference to FIGS. 8A to 8H is a method of producing the single-sided dual-layer optical disk 21, the second preferred embodiment according to the present invention.

The first intermediate disk structure D_{A} in the second embodiment is produced in the same way as the counterpart D_{A} in the first embodiment.

The second intermediate disk structure D_{B} in the second embodiment is produced as explained below.

[Photoresist Pattern Forming Process]

As shown in FIG. 8A, a 90 nm-thick photoresist 12 is applied onto a disk-like glass substrate 16.

Next, as shown in FIG. 8B, the photoresist 12 is exposed to a laser beam Le1 having a first laser power for not reaching the surface of the substrate 16. The photoresist 12 is then exposed further to a laser beam Le2 having a second laser power, stronger than the first laser power, for reaching the surface of the substrate 16. The laser beam Le2 may be emitted before the laser beam Le1.

The exposure is followed by development to form a photoresist pattern 22 having a concave section 22a which covers the glass substrate 16 and an opening 22b through which the substrate 16 is exposed. The hole 22b is formed as wobbling on both sides.

[First Dry Etching Process]

As shown in FIG. 8C, a first dry etching process is performed with CF₄ as an etching gas to form a 90 nm-deep hole 23a in the glass substrate 16 exposed through the opening 22b of the photoresist pattern 22. The pattern 22 is not etched in this process.

[Ashing Process]

Next, as shown in FIG. 8D, a ashing process is performed with oxygen gas to the photoresist pattern 22 so that the concave section 22a is removed to expose the glass substrate 16. The substrate 16 is not etched in this process.

[Second Dry Etching Process and Glass Master Plate Production Process]

As shown in FIG. 8E, a second dry etching process is performed with CF₄ as an etching gas to etch the exposed substrate 16 by 30 nm to form an opening 24. The second dry etching process further etches the substrate 16 through the hole 23a. The resultant hole 23b has a thickness of 120 nm which is 30 nm deeper (the same depth as 30 nm of the opening 24) than the hole 23a formed in the first dry etching process.

The second dry etching process is followed by ashing with oxygen gas to completely remove the photoresist pattern 22, thus a glass master plate 25 being produced.

[Master Stamper Production Process]

As shown in FIG. 8F, nickel is applied at a thickness in the range from 50 to 200 nm on the glass master plate 25 by sputtering. Then, a nickel film having a thickness in the range from 100 to 500 μm is formed thereon by electroforming. Thus, a master stamper 26 is produced as having a convex section 26a and a concave section 26b with a height lower than the convex section 26a when viewed form a bottom surface 26c. The master stamper 26 has an inverse pattern to that of the glass master plate 25.

[Mother Stamper Production Process]

The master stamper 26 is removed from the glass master plate 25. As shown in FIG. 8G, a nickel film is formed on the master stamper 26 by electroforming to transfer the pattern of the stamper 26. Thus, a mother stamper 27 is produced as having a hole 27a and another hole 27b shallower than the hole 27a when viewed form a bottom surface 27c. The stamper 27 has a pattern identical to that of the glass master plate 25.

[Second Substrate Production Process]

The mother stamper 27 is attached to an injection molding machine (not shown). A second substrate 10 is then produced by resin injection molding, which has a groove 10a and a land 10b with land pre-pits 10d thereon, formed spirally from the inner to outer periphery or vice versa, as shown in FIG. 8H.

This process is followed by several processes like those from [Second Reflective Layer Production Process] to [Second Transparent Protective Layer Production Process] disclosed with reference to FIGS. 5A to 5H in the first embodiment, to produce the second intermediate disk structure D_{B} shown in FIGS. 7A and 7B.

A bonding process like [Bonding Process] in the first embodiment is performed to bond the first and second intermediate disk structures D_{A} and D_{B} to each other, thus producing the optical disk 21 having two recording layers on one side, as shown in FIG. 7A.

As disclosed above in detail, in the second embodiment, the second substrate 10 is produced by using the mother stamper 27 having the hole 27a and the other hole 27b shallower than the hole 27a when viewed form the bottom surface 27c.

This production process gives the second substrate 10 the groove 10a, the land 10b, and the land pre-pits 10d on the land 10b which are closer to the beam incident surface 201 than the surface of the groove 10a is. This structure prevents crosstalk in reproduction between the land pre-pits 10d and recorded marks recorded on the groove 10a when the marks are formed in the data-storage area 8a of the second recording layer 8, thus achieving accurate detection of the land pre-pits 10d.

Discussed next is evaluation of recording and reproduction characteristics of a sample optical disk S4 and comparative sample disks CS1 to CS3 with different materials for the component layers that were produced in accordance with the second embodiment of the optical disk according to the present invention disclosed above.

The material used for the first and second substrates 2 and 10 for the sample and comparative sample disks was a polycarbonate resin. However, different from the samples S1 to S3 in the first embodiment, the sample and comparative sample disks in the second embodiment were produced without a first transparent protective layer 5.

[Sample 4]

Produced first was a sample-4 first intermediate disk structure D_{A}.

A 0.6 mm-thick first substrate 2 with a 0.74 μm-track pitch was produced, using the master stamper 15 shown in FIG. 4C, as having a groove 2a of 160 nm in depth and 0.3 μm in width, a land 2b of 160 nm in height from the bottom of the groove 2a and 0.44 μm in width, and land pre-pits 2c, on the land 2b, with a pattern having the same height as the land 2b.

Cyanine (S06-DX001® made by Hayashibara Co. Ltd.) exhibiting 585 nm in maximum absorption wavelength was dissolved in tetrafluoropropanol to prepare a 1.0-wt % solution.

The solution was applied onto the first substrate 2. The substrate 2 was then rotated at 1500 rpm in spin coating. Thus, a first recording layer 3 was formed as having a thickness of 50 nm. A 10 nm-thick Ag-made first reflective layer 4 was formed on the first recording layer 3 by sputtering.

Accordingly, the sample-4 first intermediate disk structure D_{A} was produced.

Produced next was a sample-4 second intermediate disk structure D_{B}.

A 0.6 mm-thick second substrate 10 with a 0.74 μm-track pitch was produced, using the mother stamper 27 shown in FIG. 8H, as having a groove 10a of 30 nm in depth and 0.3 μm in width, a land 10b of 30 nm in height from the bottom of the groove 10a and 0.44 μm in width, and land pre-pits 10d, on the land 10b, with a pattern having a height of 120 nm (90 nm beyond the groove 10a). A 100 nm-thick Ag-made second reflective layer 9 was formed on the second substrate 10 by sputtering.

Cyanine (S06-DX001® made by Hayashibara Co. Ltd.) exhibiting 585 nm in maximum absorption wavelength was dissolved in tetrafluoropropanol to prepare a 1.2-wt % solution.

The solution was applied onto the second reflective layer 9. The second substrate 10 was then rotated at 1000 rpm in spin coating. Thus, a second recording layer 8 was formed as having a thickness of 70 nm on the groove 10a.

A 20 nm-thick second transparent protective layer 7 made of ZnS—SiO₂ (ZnS:SiO₂=20:80 mol %) is then formed on the second recording layer 8 by RF sputtering.

Accordingly, the sample-4 second intermediate disk structure D_{B} was produced.

The sample-4 first and second intermediate disk structures D_{A} and D_{B} were bonded to each other. In detail, a transparent adhesive layer 6 made of a UV-cured resin was applied on the first recording layer 4 of the first intermediate disk structure D_{A}. The second intermediate disk structure D_{B} was then placed on the adhesive layer 6 so that the second transparent protective layer 7 faced the adhesive layer 6. The disk structures D_{A} and D_{B} were rotated at 6000 rpm so that the adhesive layer 6 was spread over the protective layer 7, with a thickness of 50 μm, followed by exposure to ultraviolet rays. The UV cure resin used for the transparent adhesive layer 6 was modified urethane acryate (DVD1142® made by Nippon Kayaku Co. Ltd.).

Accordingly, a sample-4 optical disk 21 was produced as having the two recording layers 3 and 8 on one side.

[Comparative Samples 1 to 3]

Comparative sample-1, -2 and -3 optical disks 21 were produced in the same way as the sample-4 optical disk 21 except for the second recording layer 8 having a thickness of 25 nm, 60 nm and 100 nm, respectively.

[Evaluation of Recording/Reproduction]

Recording and reproduction characteristics were evaluated for the sample-4 optical disks 21 and the comparative sample-1, -2 and -3 optical disks 21 with an optical disk standard evaluator (DDU-1000 made by Pulse Tech Co., equipped with an objective lens with NA=0.65).

A recording/reproduction laser beam having a wavelength of 658 nm was focused onto the data-storage areas 3a and 8a of the first and second recording layers 3 and 8, respectively, from the first substrate 2 side while each disk was being rotated at a linear velocity of 7 m/s.

A DVD-format signal was recorded in the data-storage areas 3a and 8a for each disk at a recording peak power of 14 mW with recording strategy in accordance with the DVD-R standards.

Under these requirements, each disk exhibited low and high reflectivity in recorded and un-recorded sections, respectively, in the data-storage areas 3a and 8a of the first and second recording layers 3 and 8, respectively. This is so called “high to low” recording.

Evaluation results for the sample-4 optical disks 21 were: 7.8% in jitters in reproduction and 19% in reflectivity for the data-storage area 3a of the first recording layer 3; and 8.0% in jitters in reproduction and 19% in reflectivity for the data-storage area 8a of the second recording layer 8. It was thus confirmed that excellent recording was performed for both recording layers. The reflectivity of 19% satisfies the single-sided dual-layer DVD standards for both recording layers.

The measurement of AR (aperture Ratio) gained 15% from the data-storage area 8a of the second recording layer 8. This is an index of quality of land pre-pit signals before and after recording. The AR level of 15% goes over 10% that is a single-sided dual-layer DVD standard AR level. It was thus confirmed land pre-pit signals of enough amplitude were gained.

In contrast, the comparative sample-1, -2 and -3 optical disks 21 exhibited 10%, 14% and 16%, respectively, in reflectivity, which do not satisfy the single-sided dual-layer DVD standards.

The evaluation reveals that one requirement for the second recording layer 8 is its thickness on the groove 10a, which has to be three times or more larger than the height of the land 10b.

Also produced in the same way as the sample-4 optical disk 21 were samples S_{A} to S_{I} having the same 140 nm-thick second recording layer 8 but with different depths in the range from 10 to 50 nm for the groove 10a of the second substrate 10.

Evaluated for the samples S_{A} to S_{I} were reflectivity and push-pull (P-P) signals, as shown below.

| | DEPTH in GROOVE | REFLECTIVITY | |
|---|---|---|---|
| SAMPLE | 10a (nm) | (%) | P-P SIGNAL |
| S_{A} | 10 | 21 | 0.18 |
| S_{B} | 15 | 20 | 0.19 |
| S_{C} | 20 | 18 | 0.22 |
| S_{D} | 25 | 18 | 0.24 |
| S_{E} | 30 | 17 | 0.26 |
| S_{F} | 35 | 16 | 0.27 |
| S_{G} | 40 | 16 | 0.28 |
| S_{H} | 45 | 14 | 0.29 |
| S_{I} | 50 | 12 | 0.31 |

The results show that the samples S_{C}, S_{D}, S_{E}, S_{F}, and S_{G} only exhibited 16% or higher in reflectivity and 0.22 or higher in push-pull signal that satisfy the single-sided dual-layer DVD standards.

It is thus confirmed that one requirement for the groove 10a of the second intermediate disk structure D_{B} is the depth that is in the range from 20 to 40 nm which offers higher reflectivity and more accurate tracking.

As disclosed above in detail, the present invention employs the pre-pits carrying auxiliary information, such as addresses, formed on the convex sections with respect to the beam incident surface for a laser beam in recording or reproduction. The arrangements allow common addressing to two or more of recording layers.

Particularly, in the second embodiment, the pre-pits of the second substrate are formed so that they are closer to the beam incident surface than the surface of the concave section is. This structure prevents a recoded mark from being diffused towards the pre-pits which could otherwise occur when the mark is formed in the data-storage area of the second recording layer, due to thermal diffusion. Therefore, the present invention prevents crosstalk in reproduction, and hence offering enough amplitude for land pre-pit signals.

The depth of the concave section in the second substrate is in the range from 20 to 40 nm, particularly, for the second embodiment, which offers accurate tracking.

The master stamper and the mother stamper are used for production of the first and second substrates, respectively, which allow formation of pre-pits in the convex sections and recording to the concave sections with respect to the beam incident surface.

Particularly, the mother stamper is used for production of the second substrate having the second concave section, the second convex section, and the pre-pits on the second convex section. It allows formation of the second concave section closer to the beam incident surface, the second convex section far from the incident surface, and the pre-pits closer to the incident surface than the second concave section is.

What is claimed is:

1. A method of producing an optical disk comprising the steps of:
producing a first transparent substrate having a first surface and a second surface, by using a pre-produced first master stamper, the first surface being a beam incidence surface for a laser beam in recording or reproduction, and the second surface having a first concave section and a first convex section formed thereon, the first convex section having at least one first pre-pit;
forming at least a first recording layer and a first reflective layer in order on the first substrate via the first concave and convex sections and the first pre-pit, thus producing a first intermediate disk structure;
applying a photoresist onto a glass substrate, followed by exposure and development to form a photoresist pattern on the photoresist, the photoresist pattern having a concave section and a first opening reaching a surface of the glass substrate, followed by first dry etching to a first surface portion of the glass substrate exposed through the first opening to form a first hole in the glass substrate;
ashing the photoresist pattern to remove the concave section thereof, thus a second surface portion of the glass substrate being exposed, followed by second dry etching to the glass substrate through the second exposed surface and the first hole to form a second opening in the second exposed surface and to dig the first hole by the same depth as the second opening to from a second hole, followed by removal of the photoresist pattern, thus producing a glass master plate;
producing a master stamper by transfer of the glass master plate, followed by production of a mother stamper by transfer of the master stamper, thus producing a second substrate having a second concave section and a second convex section formed thereon, the second concave section having at least second pre-pit, the second pre-pit being higher than the second convex section, by using the mother stamper;
forming at least a second recording layer and a second reflective layer in order on the second substrate via the second concave and convex sections and the second pre-pit, thus producing a second intermediate disk structure; and
bonding the first and second intermediate disk structures each other so that the first reflective layer faces the second recording layer.
